(19) United States
(12) Patent Application Publication
(10) Pub. No.: US 2012/0216863 A1
(43) Pub. Date: Aug. 30, 2012

(54) SOLAR ENERGY CONCENTRATOR ARCHITECTURES

(75) Inventors: Bing Wen, Thousand Oaks, CA (US); Jiangtao Cheng, Denton, TX (US); Chung-Lung Chen, Thousand Oaks, CA (US)

(73) Assignee: Teledyne Scientific & Imaging, LLC

(21) Appl. No.: 13/281,763

(22) Filed: Oct. 26, 2011

Related U.S. Application Data
(60) Provisional application No. 61/446,964, filed on Feb. 25, 2011.

(51) Int. Cl. H01L 31/0232

(52) U.S. Cl. 136/259

(57) ABSTRACT

Solar energy concentrator architectures employ an array of electro-optical liquid prism modules to deflect sunlight onto PV cells. Without any mechanical moving parts, the dynamic liquid prism allows the concentrator to adaptively track the daily changes of the sun's orbit. The liquid prism modules may be arranged, for example, into a sheet-shaped beam steering array; a condenser device such as a Fresnel lens is then used to focus the light deflected by the modules onto one or more PV cells—preferably CPVs. Another possible concentrator architecture requires arranging a plurality of liquid prism modules into a semi-spherical pattern, such that light impinging on the modules is directed onto one or more PV cells or CPVs.

### RELATED APPLICATIONS

This application claims the benefit of provisional patent application No. 61/446,964 to Wen et al., filed Feb. 25, 2011.

### FIELD OF THE INVENTION

This invention is directed to solar energy concentrators, and more particularly on solar energy concentrators which employ an optofluidic system based on electrowetting to deflect incoming sunlight onto photovoltaic (PV) cells.

### BACKGROUND

Much effort is being expended on the quest to efficiently obtain electrical energy from the sun. One current approach involves providing a large array of photovoltaic (PV) cells, which must be mechanically re-oriented throughout the day in order to properly track the incoming sunlight and thereby maximize the array's electrical output. An alternative approach requires that a large array of mirrors be mechanically re-oriented throughout the day in order to properly reflect and concentrate the incoming sunlight onto a receiver. These systems have several drawbacks. PV cells tend to be costly, and thus a large array of such cells may be prohibitively expensive. In addition, both of these approaches require mechanical systems to track the sun; such systems are typically expensive, consume large amounts of power, and can be difficult to maintain.

“High efficiency PV cells”, also known as “concentrated” PV cells (CPVs) can be used to increase the electrical output of a solar energy system. However, CPVs are very expensive and would not be practical for use in a large array.

### SUMMARY OF THE INVENTION

Solar energy concentrator architectures are presented which overcome the problems identified above, providing tracking of the sun without a mechanical system and enabling sunlight to be easily concentrated on an array of PV cells or CPVs.

Several solar energy concentrator architectures are described, each of which employs an array of electro-optical devices to deflect sunlight onto PV cells. The preferred electro-optical device is a liquid prism module that employs the electrowetting-on-dielectric (EWOD) principle. Each module comprises a container having a plurality of sidewalls, at least one of which includes an electrode layer and a dielectric layer. At least one liquid fills a portion of the container and contacts the electrode-containing sidewalls. When the container is transparent and contains two immiscible fluids, and voltages are applied to the electrode-containing sidewalls, the interface of the two liquids tilts to bend the beam. In other words, the contact angle along the fluid-fluid-solid tri-junction line—and hence the orientation of the fluid-fluid interface—can be actively controlled via electrowetting. When the immiscible fluids have difference refractive indices, the naturally-formed meniscus between the two liquids functions as an optical prism. Without any mechanical moving parts, this dynamic liquid prism allows the concentrator to adaptively track the daily changes in the sun's orbit. The present system eliminates the power consumption, bulky tracking hardware and noise associated with mechanical tracking.

The concentrator's electro-optical devices may be arranged, for example, into a sheet-shaped array, and include a condenser device such as a Fresnel lens to focus the light deflected by the modules onto one or more PV cells—preferably CPVs. Two or more sheet-shaped arrays may be stacked so as to increase the angle with which light can be deflected.

Another possible concentrator architecture requires arranging a plurality of electro-optical devices into a semi-spherical pattern, such that light impinging on the modules is directed onto one or more PV cells or CPVs.

These and other features, aspects, and advantages of the present invention will become better understood with reference to the following drawings, description, and claims.

### BRIEF DESCRIPTION OF THE DRAWINGS

The detailed description of embodiments of the invention will be made with reference to the accompanying drawings, wherein like numerals designate corresponding parts in the figures.

FIG. 1a is a diagram of a liquid prism module as might be used as part of a solar energy concentrator architecture per the present invention.

FIG. 1b is a diagram illustrating the layers and the operation of a liquid prism module as shown in FIG. 1a

FIG. 2 is a diagram illustrating one possible solar energy concentrator architecture per the present invention.

FIG. 3 is an illustration of another possible solar energy concentrator architecture per the present invention.

FIG. 4 is a diagram illustrating the effect of using two vertically aligned liquid prism module arrays on the deflection of incoming sunlight.

FIG. 6 is a diagram illustrating an electrowetting-controlled solar energy concentrator system which employs two arrays of liquid prism modules and multiple PV cells.

### DETAILED DESCRIPTION OF THE INVENTION

Several unique solar energy concentrator architectures are described herein, each of which employs an array of electro-optical devices to deflect sunlight onto PV cells. Any type of electro-optical device capable of deflecting incoming sunlight may be employed, including, for example, a liquid crystal device or a Risley prism. The preferred device is a electro-optical prism that employs the electrowetting-on-dielectric (EWOD) principle. The term “liquid prism module” is used herein to refer to this type of prism, which appears in all of the illustrated embodiments; note, however, that the present solar energy concentrator architectures may also employ other electro-optical device types.

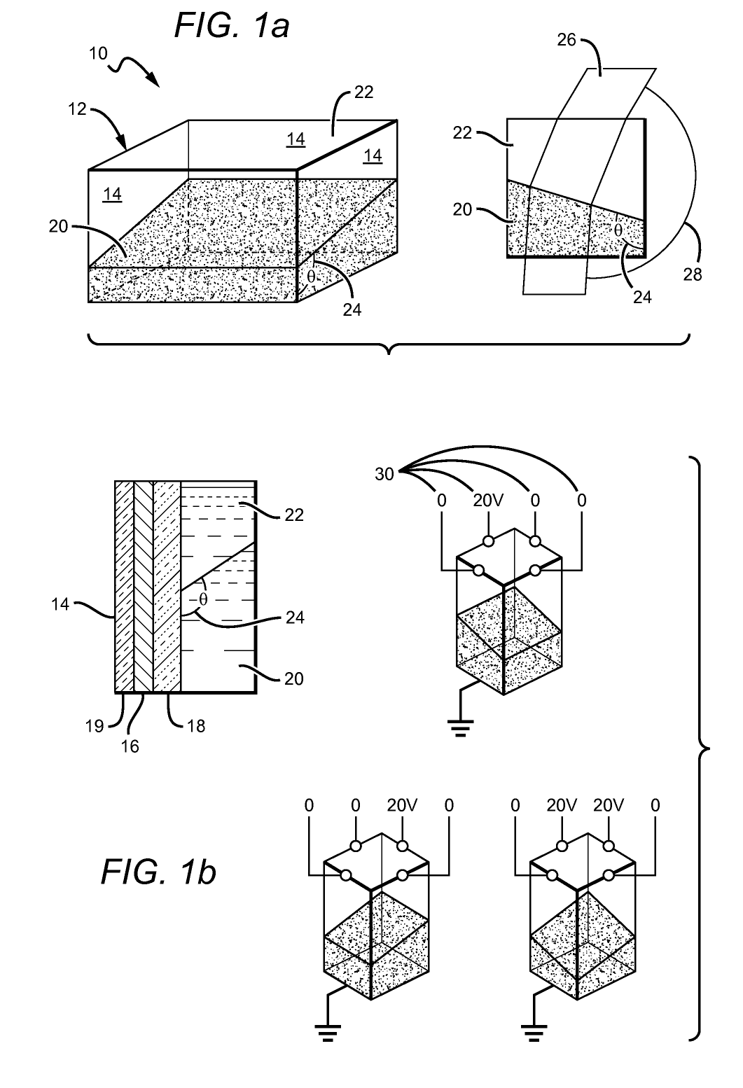

An exemplary embodiment of such a liquid prism module is shown in FIG. 1a, with additional details shown in FIG. 1b. Each liquid prism module 10 comprises a container 12 having a plurality of sidewalls 14, at least one of which includes an electrode layer 16, preferably a thin transparent layer of a material such as indium tin oxide (ITO), and a dielectric layer 18 which is preferably hydrophobic; an outer layer 19 such as glass would typically be on the outside of electrode layer 16. At least one liquid fills a portion of the container and contacts the electrode-containing sidewalls; the container preferably contains two immiscible fluids 20, 22 having different refractive indices, such as water and a non-polar oil. It is preferable that the densities of the two fluids be approximately equal. The top and bottom surfaces of container 12 are preferably coated to be anti-reflective. When the container is transparent and contains two immiscible fluids, and appropriate voltages are applied to the electrode-containing sidewalls, the interface of the two liquids tilts and thereby deflects any light passing through the interface. In other words, the contact angle θ (24) along the fluid-fluid-solid tri-junction line—and hence the orientation of the fluid-fluid interface—can be actively controlled via electrowetting. The naturally-formed meniscus between the two liquids functions as an optical prism capable of deflecting incoming sunlight 26 at an angle 28 determined by the contact angle. Without any mechanical moving parts, this dynamic liquid prism allows the present concentrator to adaptively track the sun's orbit, by simply adjusting the voltages 30 applied to a module's electrode-containing sidewalls. This enables a solar energy concentrator per the present system to eliminate the power consumption, bulky tracking hardware and noise associated with the mechanical tracking schemes employed by other systems.

Note that a prism as shown in FIGS. 1a and 1b might also include a reflector (not shown) having a bottom surface which is in contact with the top surface of liquid 20 and a top surface which is reflective, such that the reflector's orientation varies with the contact angle between liquid 20 and the electrode-containing sidewalls. When so arranged, the prism can be used to reflect incoming sunlight at a desired angle, rather than deflect the incoming light.

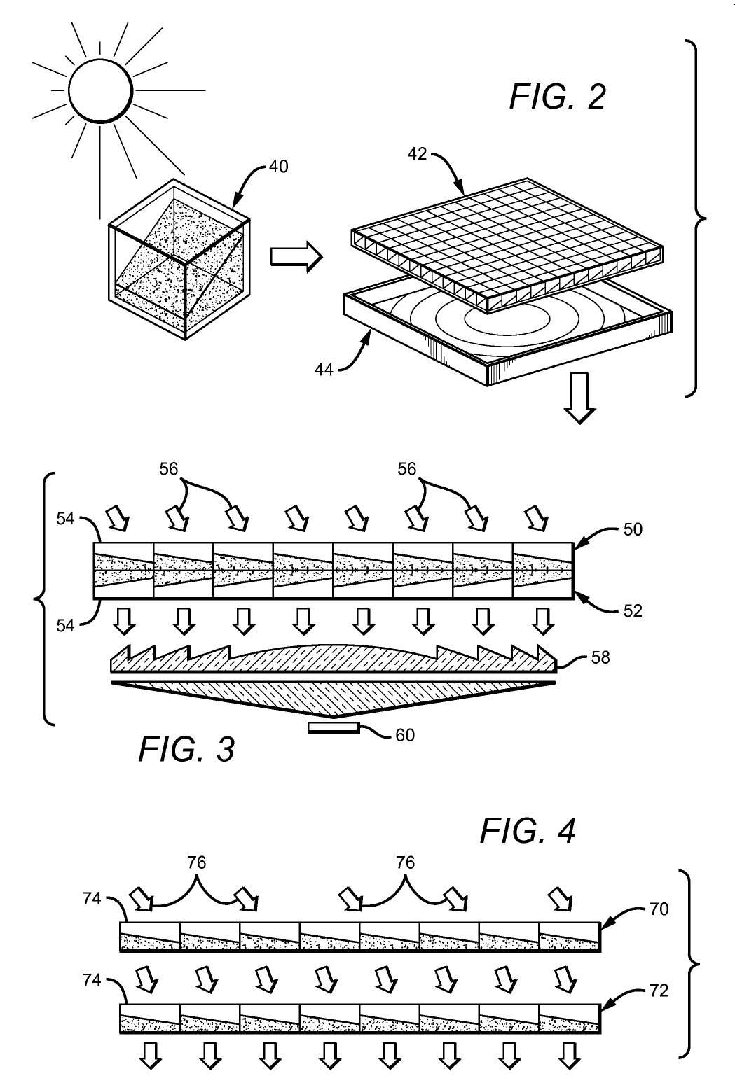

One possible embodiment of a solar energy concentrator per the present invention is shown in FIG. 2. Here, liquid prism modules 40 as described above are arranged into a sheet-shaped “beam steering” array 42. The solar concentrator preferably includes a condenser device 44 which is placed beneath the array 42 and is arranged to focus light deflected by the modules onto one or more PV cells (not shown). A preferred condenser device is a Fresnel lens, and the preferred PV cells are concentrated PV cells (CPVs).

A sectional view of another possible embodiment of a solar energy concentrator per the present invention is shown in FIG. 3. Here, there are two sheet-shaped beam steering arrays 50, 52, each formed from multiple liquid prism modules 54, with one array stacked atop the other. The arrays deflect incoming sunlight 56 onto a condenser device 58, which focuses the light onto a PV cell 60—which may be a relatively small (several mm) CPV cell. Condenser device 58 is preferably a non-reflective-coated optical acrylic Fresnel lens, which can be arranged to capture light from an area >1000 times that of the CPV cell and focus it onto cell 60. Each hexagonal shaped Fresnel lens segment is preferably identical, so no scaling of this component is required between various configurations. The solar energy concentrator can track the sun by simply changing the steering direction of each liquid prism, with no mechanical moving parts involved. Note that manipulating the contact angles of the respective liquid prism modules as shown in FIG. 3 tends to maximize the achievable deflection angle.

As previously noted, the present system preferably employs high-efficiency CPV PV cells. Preferred CPV cells employ III-V materials, and are more efficient than traditional silicon-based PV cells (40% vs. 15%-19%). The use of these cells provides a much higher energy yield with less PV material.

The EWOD mechanism employed by the liquid prism modules described herein is used as a surface-tension-control technique. The contact angle change of a liquid by electrowetting is described by Lippman-Young's equation:

cos θ=cos θ_{Y}+[∈∈₀)/(2γd)]V²,

where θ is the contact angle at electric potential V, θ_{Y} is the contact angle with no electric potential, γ is the liquid-liquid interfacial tension, ∈₀ is the permittivity of vacuum, ∈ is the dielectric constant of the insulator layer, and d the thickness of the dielectric insulation layer. Changes in the contact angle can give rise to continuous variations of the fluid-fluid interface curvature and shape. Therefore, the meniscus interface can function as a liquid prism (light deflector) or as a tunable optical lens. Note that if there is only one type of liquid in the cell, γ is the surface tension between the liquid and the vapor (air, gas, etc.) contained within the cell.

As shown in FIG. 4, two or more sheet-shaped arrays 70, 72 of liquid prism modules 74 can be stacked, so that incoming light 76 may be deflected with a large steering angle) (>45°).

The present solar energy concentrator can be arranged to continuously align the liquid prism array to deflect sunlight throughout the day so as to maximize electricity generation. This type of design is also lighter and smaller than conventional concentrators, and thus can provide a highly efficient system suitable for rooftop installation.

The present solar energy concentrator can be arranged as a “1-D” embodiment, in which only one independent voltage is applied to a sidewall of each prism module. A “2-D” embodiment which provides 2-D steering can be achieved by providing two independent voltages to respective sidewalls of each cell. A 2-D arrangement enables the concentrator to adaptively track both daily and seasonal changes in the sun's orbit, i.e., dual-axis tracking is provided. The voltages applied to the electrode layers of each module may be approximately equal for every module in an array, in which case the contact angle for each module would be approximately equal and would change in unison. Alternatively, the voltages applied to the electrode layers may be independent for every module in an array. A controller (not shown) would typically be provided to apply the voltages to the electrode layers. An electrowetting-controlled liquid prism module as described herein can provide a wide sun tracking range in excess of ±30°.

A controller is used to apply the necessary voltages to the electrode-containing sidewalls of the liquid prism modules. The voltages may be either DC or AC. The advantages of DC control are low power consumption and fabrication simplicity. However, the dielectric coating on the module walls may be subject to breakdown or permanent polarization when a high DC electric field is applied over an extended period. Using an AC voltage avoids applying a high electric field over a long period to an electrode-containing sidewall, which can significantly increase the reliability and service life of the solar energy concentrator; however, this approach may consume more power and is relatively more complicated. The controller is preferably arranged such that, once programmed, it runs without human intervention—automatically controlling the voltages applied to the sidewalls according to the latitude of the solar energy concentrator and the time of day, so that maximal solar energy is concentrated on the PV cells.

One or more beam steering sheets can be easily scaled to cover a large surface, or form a large energy farm; one possible embodiment is shown in FIG. 5. Here, two sheet-shaped arrays 80 and 82 are stacked, and a condenser layer 84 is arranged to focus the light deflected by predetermined groups of prisms onto multiple PV cells 86—preferably CPVs. With a distributed arrangement of PV cells such as that shown in FIG. 5, heat dissipation can be well-managed so that device performance and reliability can be ensured.

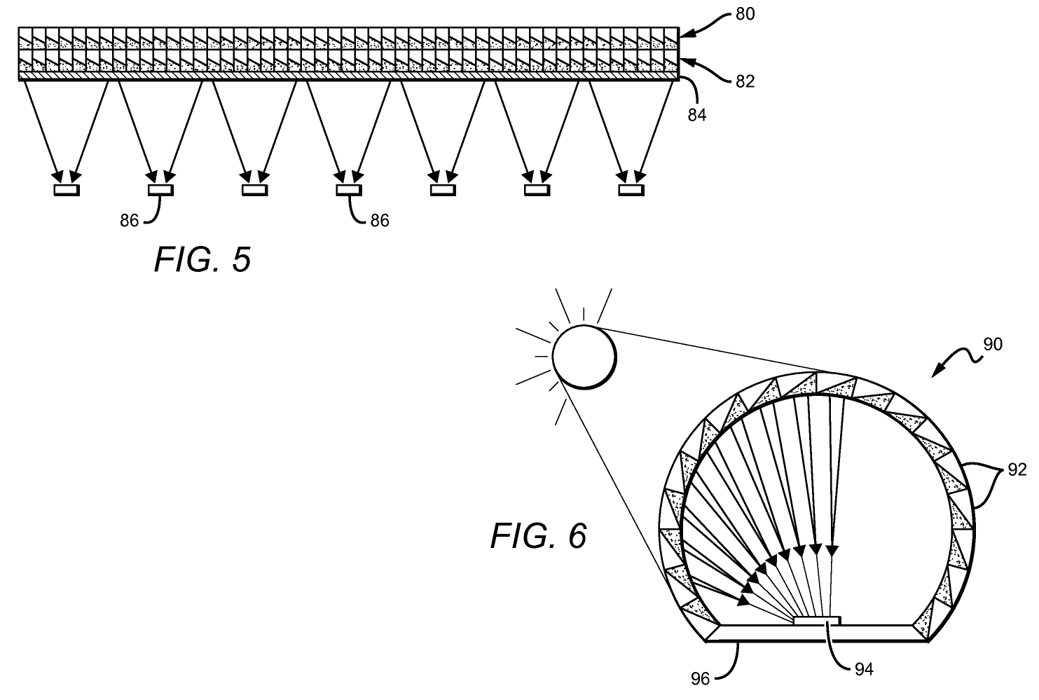

Another possible solar energy concentrator architecture 90 in accordance with the present invention is illustrated in FIG. 6. Here, the liquid prism modules 92 are arranged in a semi-spherical pattern, by mounting them on the surface of a sphere or a dome, for example, such that light impinging on the modules is directed onto one or more PV cells 94 which would typically be mounted on a substrate 96. Sunlight passing through the modules is deflected and collimated towards the PV cell—preferably a CPV—situated on substrate 96. The incidence direction of sunlight can be detected by a quad cell which could be part of the PV-cell itself, or estimated according to the time of day and season without additional measurement. The semi-spherical array of modules 92 represent a larger lens that is able to intensively concentrate solar energy. Both the focus power and focal point of such a solar energy concentrator can be adjusted as needed. In this exemplary embodiment, the whole concentrator uses only one small CPV cell 94 on substrate 96, and is able to track the sun without any moving parts. For a dome-shaped concentrator, the effective collecting area is given by πR², where R is the radius of the dome. It is estimated that at least half of the incoming solar energy would be deflected towards PV cell 94, independent of the solar position.

Various other modifications and alterations in the structure and method of operation of this invention will be apparent to those skilled in the art without departing from the scope and spirit of the invention. Although the invention has been described in connection with specific preferred embodiments, it should be understood that the invention as claimed should not be unduly limited to such specific embodiments. It is intended that the following claims define the scope of the present invention and that structures and methods within the scope of these claims and their equivalents be covered thereby.

We claim:

1. A solar energy concentrator architecture, comprising:
a plurality of electro-optical devices capable of deflecting incoming light, said devices arranged into a sheet-shaped beam steering array;
a condenser device arranged to focus said light deflected by said modules; and
one or more PV cells, said electro-optical devices and PV cells arranged such that said condenser device focuses said light deflected by said devices onto said cells.

2. The architecture of claim 1, wherein said condenser device is a Fresnel lens.

3. The architecture of claim 1, wherein said PV cells are concentrated PV cells (CPVs).

4. The architecture of claim 1, wherein two or more of said sheet-shaped beam steering arrays are stacked so as to increase the angle with which said light can be deflected.

5. The architecture of claim 1, wherein each of said electro-optical devices is a liquid prism module, each of said modules comprising:
a container having a plurality of sidewalls, at least one of said sidewalls being an electrode-containing sidewall comprising:
an electrode layer; and
a dielectric layer on said electrode layer; and
first and second liquids which fill a portion of said container and contact said electrode-containing sidewalls, said first and second liquids being immiscible and in contact with each other at the liquid-liquid interface, such that the contact angle along the liquid-liquid-solid tri-junction line and hence the orientation of the liquid-liquid interface varies with the voltages applied to said electrode layers, such that the naturally-formed meniscus between said first and second liquids functions as an optical prism that deflects light which passes through said meniscus.

6. A solar energy concentrator architecture, comprising:
a plurality of electro-optical devices capable of deflecting incoming light, said devices arranged into a semi-spherical pattern; and
one or more PV cells, said electro-optical devices and PV cells arranged such light impinging on said devices is directed onto said cells.

7. The architecture of claim 6, wherein said PV cells are concentrated PV cells (CPVs).

8. The architecture of claim 6, wherein each of said electro-optical devices is a liquid prism module, each of said modules comprising:
a container having a plurality of sidewalls, at least one of said sidewalls being an electrode-containing sidewall comprising:
an electrode layer; and
a dielectric layer on said electrode layer; and
first and second liquids which fill a portion of said container and contact said electrode-containing sidewalls, said first and second liquids being immiscible and in contact with each other at the liquid-liquid interface, such that the contact angle along the liquid-liquid-solid tri-junction line and hence the orientation of the liquid-liquid interface varies with the voltages applied to said electrode layers, such that the naturally-formed meniscus between said first and second liquids functions as an optical prism that deflects light which passes through said meniscus.

9. A solar energy concentrator, comprising:
a plurality of liquid prism modules, each of which comprises:
a container having a plurality of sidewalls, at least one of said sidewalls being an electrode-containing sidewall comprising:
an electrode layer; and
a dielectric layer on said electrode layer; and
first and second liquids which fill a portion of said container and contact said electrode-containing sidewalls, said first and second liquids being immiscible and in contact with each other at the liquid-liquid interface, such that the contact angle along the liquid-liquid-solid tri-junction line and hence the orientation of the liquid-liquid interface varies with the voltages applied to said electrode layers, such that the naturally-formed meniscus between said first and second liquids functions as an optical prism that deflects light which passes through said meniscus; and
one or more PV cells, said modules and cells arranged such that said optical prisms can be oriented to deflect light impinging on said module onto said cells.

10. The solar energy concentrator of claim 9, wherein the orientation of the interface between said liquids varies with said contact angle, further comprising a reflector having a bottom surface which is in contact with the top surface of the lower of said liquids and a top surface which is reflective, said reflector arranged such that its orientation varies with said contact angle.

11. The solar energy concentrator of claim 10, wherein said modules and PV cells are arranged such that said reflector can be oriented to reflect light impinging on said modules onto said cells.

12. The solar energy concentrator of claim 11, wherein said PV cells are concentrated PV cells (CPVs).

13. The solar energy concentrator of claim 9, wherein the densities of said first and second liquids are approximately equal.

14. The solar energy concentrator of claim 9, wherein said PV cells are concentrated PV cells (CPVs).

15. The solar energy concentrator of claim 9, wherein said container comprises a base member and four electrode-containing sidewalls which are coupled to and rise from said base member.

16. The solar energy concentrator of claim 9, wherein said electrode layer is an indium tin oxide (ITO) layer.

17. The solar energy concentrator of claim 9, wherein said dielectric layer is hydrophobic.

18. The solar energy concentrator of claim 9, wherein each of said electrode-containing sidewalls further comprises an outer layer on which said electrode layer is disposed.

19. The solar energy concentrator of claim 18, wherein said outer layer is glass.

20. The solar energy concentrator of claim 9, wherein said plurality of modules are arranged into a sheet-shaped beam steering array.

21. The solar energy concentrator of claim 20, further comprising a condenser device arranged to focus said light deflected by said modules onto said PV cells.

22. The solar energy concentrator of claim 21, wherein said condenser device is a Fresnel lens.

23. The solar energy concentrator of claim 20, wherein two or more of said sheet-shaped beam steering arrays are stacked so as to increase the angle with which said light can be deflected.

24. The solar energy concentrator of claim 9, wherein the voltages on the electrode layers of each of said modules are approximately equal for every module.

25. The solar energy concentrator of claim 9, wherein the voltages on the electrode layers of each of said modules are independent for every module.

26. The solar energy concentrator of claim 9, further comprising a controller arranged to apply said voltages to said electrode layers.

27. The solar energy concentrator of claim 26, wherein said controller is arranged to apply independently controllable voltages to at least two of said electrode layers so as to provide dual-axis control of said contact angle.

28. The solar energy concentrator of claim 26, wherein said voltages are DC voltages.

29. The solar energy concentrator of claim 26, wherein said voltages are AC voltages.

30. The solar energy concentrator of claim 9, wherein said plurality of modules are arranged in a semi-spherical pattern, said modules and cells arranged such that light impinging on said modules is directed onto said PV cells.
